(19) United States
(12) Patent Application Publication
(10) Pub. No.: US 2009/0180044 A1
(43) Pub. Date: Jul. 16, 2009

(54) THIN FILM TRANSISTOR SUBSTRATE, LIQUID CRYSTAL DISPLAY HAVING THE SAME, AND METHOD OF MANUFACTURING THE SAME

(75) Inventors: Young-Min KIM, Yongin-si (KR); Bo-Sung Kim, Seoul (KR); Jung-Han Shin, Yongin-si (KR); Tae-Young Choi, Seoul (KR); Bo-Kyoung Ahn, Incheon (KR)

Correspondence Address: H.C. PARK & ASSOCIATES, PLC, 8500 LEESBURG PIKE, SUITE 7500, VIENNA, VA, 22182, US

(73) Assignee: Samsung Electronics Co., Ltd., Suwon-si (KR)

(21) Appl. No.: 12/324,172

(22) Filed: Nov. 26, 2008

(30) Foreign Application Priority Data
Jan. 11, 2008 (KR) 10-2008-0003518

(51) Int. Cl. H01L 51/10; G02F 1/1368; H01L 51/40

(52) U.S. Cl. 349/43; 257/40; 438/99; 257/E51.006; 257/E21.411

(57) ABSTRACT

A thin film transistor substrate includes a gate line arranged on a substrate, a data line arranged to cross the gate line, an organic thin film transistor including a gate electrode connected to the gate line, a source electrode connected to the data line, a drain electrode spaced apart from the source electrode, and an organic semiconductor layer forming a channel between the source electrode and the drain electrode, a pixel electrode connected to the drain electrode, and an organic passivation layer to protect the organic semiconductor layer and to receive a white light and transmit a colored light.

### CROSS-REFERENCE TO RELATED APPLICATION

This application claims priority from and the benefit of Korean Patent Application No. 10-2008-0003518, filed on Jan. 11, 2008, which is hereby incorporated by reference for all purposes as if fully set forth herein.

### BACKGROUND OF THE INVENTION

1. Field of the Invention

The present invention relates to a liquid crystal display (LCD), and, more particularly, to a thin film transistor (TFT) substrate, an LCD having the same, and a method of manufacturing the same, which may provide for a simplified manufacturing process and reduce manufacturing costs.

2. Discussion of the Background

The advent of information society has yielded a rapidly increasing demand for a high performance display device that can display various information, such as images, graphics, text, etc., to rapidly deliver a variety of information. As a result, there has been a sharp growth in display related industries.

Liquid crystal displays (LCDs) have several advantages including low power consumption, slim and compact design, and non electromagnetic wave emission, which cause LCDs to be considered next generation displays. Moreover, LCDs have been widely used in various applications such as electronic watches, electronic calculators, personal computers, televisions, and the like.

Images are displayed on LCDs by adjusting light transmittance of liquid crystals having dielectric anisotropy using an electric field. For this, an LCD includes a display panel to display an image through a liquid crystal cell matrix and a drive circuit to drive the display panel.

In general, the respective liquid crystal cells arranged in a matrix adjust the light transmittance according to a video signal, thus displaying an image. Thin film transistors (TFTs) are used as switching elements to independently supply the video signal to each liquid crystal cell. Amorphous silicon or polysilicon may be included in an active layer of such a TFT.

However, since the amorphous silicon or polysilicon active layer may be patterned through a thin film deposition process, a photolithography process, and an etching process, the manufacturing process may be complicated.

Accordingly, there has been extensive research aimed at developing an organic transistor in which an organic semiconductor layer, which may be formed by an inkjet or coating process, is used as the active layer.

### SUMMARY OF THE INVENTION

The present invention provides a TFT substrate, a liquid crystal display (LCD) having the same, and a method of manufacturing the same, which may provide for a simplified manufacturing process and reduce manufacturing costs.

Additional features of the invention will be set forth in the description which follows, and in part will be apparent from the description, or may be learned by practice of the invention.

The present invention discloses a thin film transistor substrate including a gate line disposed on a substrate, a data line disposed to cross the gate line an organic thin film transistor that includes a gate electrode connected to the gate line, a source electrode connected to the data line, a drain electrode spaced apart from the source electrode, and an organic semiconductor layer forming a channel between the source electrode and the drain electrode, a pixel electrode connected to the drain electrode, and an organic passivation layer to protect the organic semiconductor layer and to receive a light and transmit a colored light.

The present invention also discloses a liquid crystal display including a thin film transistor substrate, an opposite substrate, and a liquid crystal layer interposed between the thin film transistor substrate and the opposite substrate. The thin film transistor substrate may include an organic thin film transistor that includes a gate electrode connected to a gate line, a source electrode connected to a data line, a drain electrode spaced apart from the source electrode, and an organic semiconductor layer forming a channel between the source electrode and the drain electrode, a pixel electrode connected to the drain electrode, and an organic passivation layer to protect the organic semiconductor layer and to receive a light and transmit a colored light.

The present invention also discloses a method of manufacturing a thin film transistor substrate including forming a first metal pattern including a gate line and a gate electrode on a substrate, forming a second metal pattern that includes a data line, a source electrode, and a drain electrode spaced apart from the source electrode, forming a bank insulating layer, which includes a first hole and a second hole, on the second metal pattern, forming an organic semiconductor layer in the first hole, and forming an organic passivation layer in the second hole. The organic passivation layer receives a light and transmits a colored light.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a plan view showing a thin film transistor (TFT) substrate in accordance with a first exemplary embodiment of the present invention.

FIG. 2 is a cross-sectional view taken along line I-I′ of FIG. 1.

FIG. 3 is a plan view showing a TFT substrate in accordance with a second exemplary embodiment of the present invention.

FIG. 4 is a cross-sectional view taken along line I-I′ of FIG. 3.

FIG.5 is a cross-sectional view showing a liquid crystal display in accordance with a third exemplary embodiment of the present invention.

FIG. 6A, FIG. 6B, FIG. 6C, FIG. 6D, FIG. 6E, FIG. 6F, FIG. 6G, and FIG. 6H are diagrams showing a method of manufacturing the TFT substrate in accordance with the first and second exemplary embodiments of the present invention.

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements.

It will be understood that when an element or layer is referred to as being “on” or “connected to” another element or layer, it can be directly on or directly connected to the other element or layer, or intervening elements or layers may be present. In contrast, when an element is referred to as being “directly on” or “directly connected to” another element or layer, there are no intervening elements or layers present.

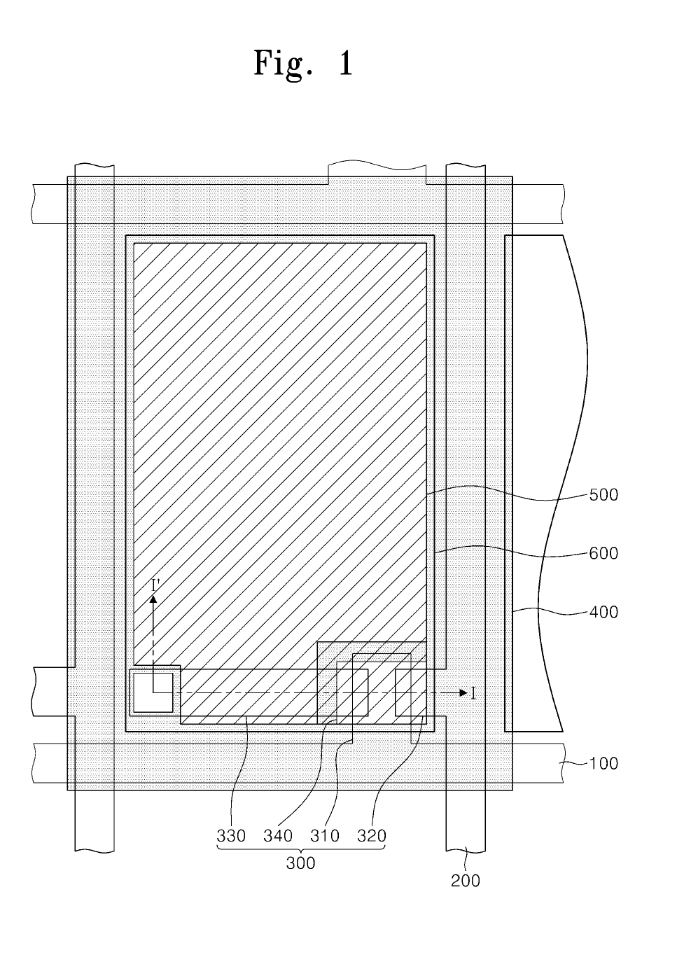

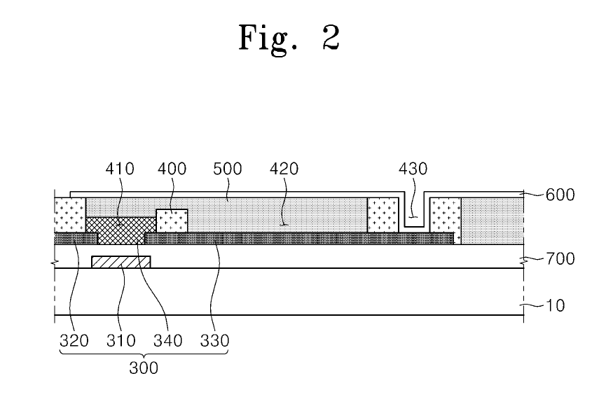

FIG. 1 is a plan view showing a thin film transistor (TFT) substrate in accordance with a first exemplary embodiment of the present invention, and FIG. 2 is a cross-sectional view taken along line I-I′ of FIG. 1. The TFT substrate in accordance with the first exemplary embodiment of the present invention will be described with reference to FIG. 1 and FIG. 2.

The TFT substrate in accordance with this exemplary embodiment of the present invention includes a gate line 100, a data line 200, a TFT 300, a pixel electrode 600, and an organic passivation layer 500. The TFT substrate may be coupled together with an opposite substrate (not shown), which includes a common electrode, and a liquid crystal layer (not shown) disposed between the substrates. Furthermore, a backlight unit (not shown) may be provided behind the TFT substrate to provide a white light that to the TFT substrate. An electric field generated by the pixel electrode 600 and the common electrode adjusts the transmittance of light through the liquid crystal layer, thereby permitting display of an image.

Referring to FIG. 1 and FIG. 2, the TFT substrate in accordance with this exemplary embodiment of the present invention includes the gate line 100 and the data line 200, which cross each other on an insulating substrate 10 with a gate insulating layer 700 interposed therebetween, the TFT 300 arranged in a sub-pixel region defined by the gate line 100 and the data line 200 and connected to the gate line 100 and the data line 200, the pixel electrode 600 disposed in the sub-pixel region and connected to the TFT 300, and the organic passivation layer 500 provided to protect an organic semiconductor layer 340 of the TFT 300.

The gate line 100 supplies a gate on/off voltage from a gate drive circuit (not shown) to a gate electrode 310 of the TFT 300. The gate line 100 may include a metal, such as copper (Cu), molybdenum (Mo), aluminum (Al), Cu alloy, Mo alloy, or Al alloy.

The data line 200 is arranged to cross the gate line 100 with the gate insulating layer 700 interposed therebetween. The data line 200 supplies a pixel signal transmitted from a data drive circuit (not shown) to the pixel electrode 600. The data line 200 may include a metal, such as, copper (Cu), molybdenum (Mo), aluminum (Al), Cu alloy, Mo alloy, or Al alloy.

The gate insulating layer 700 may include an inorganic insulating layer, such as silicon nitride (SiNₓ) or silicon oxide (SiOₓ), an organic insulating layer, or a dual insulating layer including an organic insulating layer and an inorganic insulating layer.

The TFT 300 supplies the pixel signal from the data line 200 to the pixel electrode 600 in response to the gate on/off voltage supplied from the gate line 100. The TFT 300 includes the gate electrode 310 branched from the gate line 100, a source electrode 320 branched from the data line 200, a drain electrode 330 facing the source electrode 320 and connected to the pixel electrode 600, and the organic semiconductor layer 340 that forms a channel between the source electrode 320 and the drain electrode 330.

The organic semiconductor layer 340 overlaps the gate electrode 310 with the gate insulating layer 700 interposed therebetween and forms the channel between the source electrode 320 and the drain electrode 330. The organic semiconductor layer 340 may be composed of at least one of pentacene, tetracene, anthracene, naphthalene, α-6-thiophene, α-4-thiophene, perylene and derivatives thereof, rubrene and derivatives thereof, coronene and derivatives thereof, perylenetetracarboxylic diimide and derivatives thereof, perylenetetracarboxylic dianhydride and derivatives thereof, phthalocyanine and derivatives thereof, naphthalene tetracarboxylic diimide and derivatives thereof, naphthalene tetracarboxylic dianhydride and derivatives thereof, conjugated polymer derivatives containing substituted or non-substituted thiophene, and conjugated polymer derivatives containing substituted fluorine.

The organic passivation layer 500 may cover the organic semiconductor layer 340, thus protecting the same. Since the organic passivation layer 500 contains a pigment or dye to transmit colored light from a light source, it may be possible to display a color without a color filter layer. Accordingly, the manufacturing process may be simplified and the manufacturing costs may be reduced.

The organic passivation layer 500 may transmit red, green, or blue light from the light source and may contain a pigment or dye with other components such as a binder, a monomer, an initiator, an additive, and a solvent.

Such an organic passivation layer 500 may include a composition containing a pigment or dye, a binder, a monomer, an initiator, an additive, and a solvent. In the composition for the organic passivation layer, the pigment or dye is added to provide color, the binder is added to aid dispersion stabilization and improve development effectiveness, and the monomer is added for photopolymerization and crosslinking. Moreover, the initiator is added to initiate the photopolymerization, the additive is added to improve the dispersion stabilization, coating properties and adhesion properties, and the solvent is added to improve the coating properties and processability. The solvent may be removed by a drying process after the composition for the organic passivation layer is applied. The composition for the organic passivation layer may include about 5 to about 10 wt % of the pigment or dye, about 5 to about 10 wt % of the binder, about 5 to about 10 wt % of the monomer, less than about 1 wt % of the initiator, less than about 1 wt % of the additive, and about 70 to about 85 wt % of the solvent.

Meanwhile, the organic passivation layer 500 may be arranged to overlap with the pixel electrode 600 partially or wholly, as well as on the organic semiconductor layer 340.

The organic semiconductor layer 340 and the organic passivation layer 500 may be formed using a bank insulating layer 400. In particular, the bank insulating layer may have a step height so as to define regions where the organic semiconductor layer 340 and the organic passivation layer 500 are disposed, respectively. The organic semiconductor layer 340 and the organic passivation layer 500 are filled in the regions defined by the step height of the bank insulating layer 400. That is, the bank insulating layer 400 includes partitions to provide a first hole 410, in which the organic semiconductor layer 340 is arranged, and a second hole 420, in which the organic passivation layer 500 is arranged. The second hole 420 includes the first hole 410 so that the organic passivation layer 500 may be provided to cover the organic semiconductor layer 340. In the above process, the organic semiconductor layer 340 and the organic passivation layer 500 may be formed by an inkjet method.

The pixel electrode 600 may include a transparent conductive material such as indium tin oxide (ITO), indium zinc oxide (IZO), etc. When using the bank insulating layer 400, a portion of the drain electrode 330 of the TFT 300 is exposed through a hole defined by the bank insulating layer 400, and the pixel electrode 600 is connected to the exposed portion of the drain electrode 330. The bank insulating layer 400 includes a third hole 430 to expose a portion of the drain electrode 330 so that the pixel electrode 600 may be connected to the drain electrode 330 through the third hole 430.

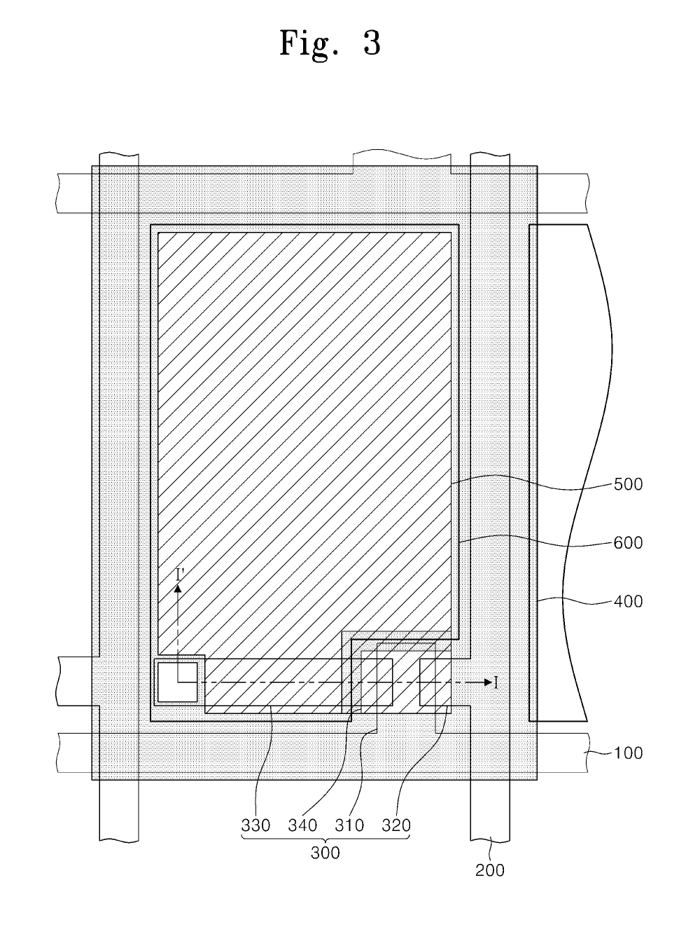

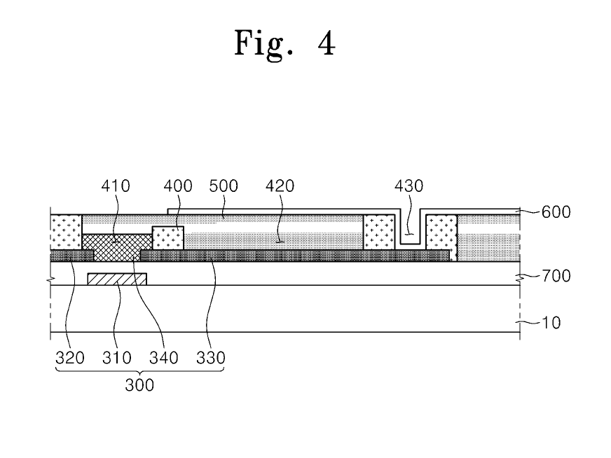

FIG. 3 is a plan view showing a TFT substrate in accordance with a second exemplary embodiment of the present invention, and FIG. 4 is a cross-sectional view taken along line I-l′ of FIG. 3. The TFT substrate in accordance with the second exemplary embodiment of the present invention will be described with reference to FIG. 3 and FIG. 4.

The TFT substrate in accordance with this exemplary embodiment includes a gate line 100, a data line 200, a TFT 300, a pixel electrode 600, and an organic passivation layer 500.

Although the pixel electrode 600 is disposed on the top of the TFT 300, as well as on the pixel region adjacent to the TFT 300 in the first exemplary embodiment, the pixel electrode 600 is disposed only on the top of the pixel region except for the top of the TFT 300 in this exemplary embodiment. Since the structure other than the pixel electrode 600 is substantially the same as that of the first exemplary embodiment, the repeated description will be omitted.

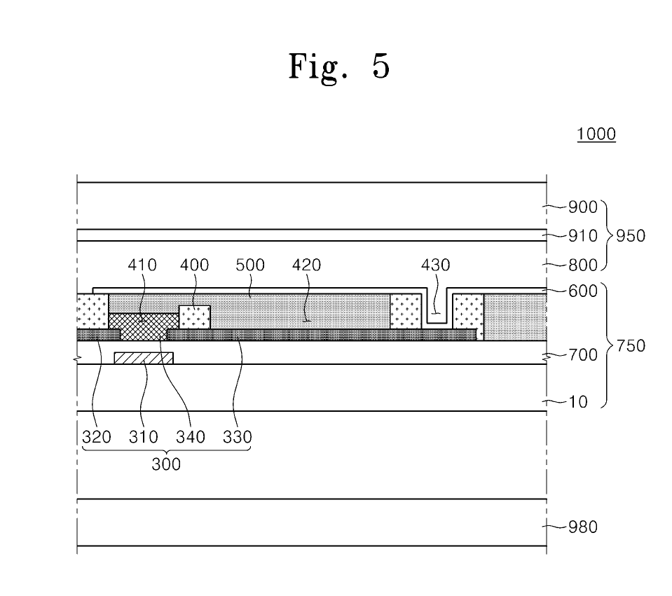

FIG.5 is a cross-sectional view showing a liquid crystal display in accordance with a third exemplary embodiment of the present invention.

Referring to FIG. 5, a liquid crystal display 1000 includes a TFT substrate 750, an opposite substrate 950, a backlight unit 980, and a liquid crystal layer 800 interposed between the TFT substrate 750 and the opposite substrate 950. The TFT substrate 750 is same as a TFT substrate (shown in FIG. 1 and FIG. 2) in accordance with a first exemplary embodiment of the present invention, and thus, the same reference numeral is assigned to the TFT substrate 750 and a detailed description of the TFT substrate 750 will be omitted.

The opposite substrate 950 includes a substrate 900 and a common electrode 910. The common electrode 910 is arranged on the substrate 900 to face a pixel electrode 600. Accordingly, an electric field generated by the pixel electrode 600 and the common electrode 910 adjusts the transmittance of light through the liquid crystal layer 800.

The backlight unit 980 is provided behind the TFT substrate 750. The backlight unit 980 may emit a white light, and thus the backlight unit 980 provides the TFT substrate 750 with the white light. As described with reference to FIG. 1 and FIG. 2, an organic passivation layer 500 contains a pigment or dye to receive the white light and transmit a colored light. Accordingly, the liquid crystal display 1000 may be possible to display a colored image without a color filter.

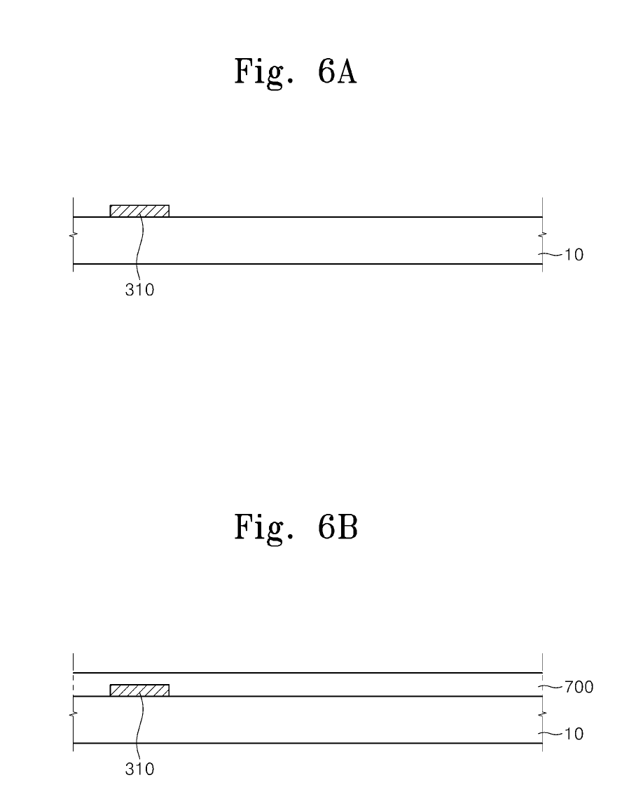

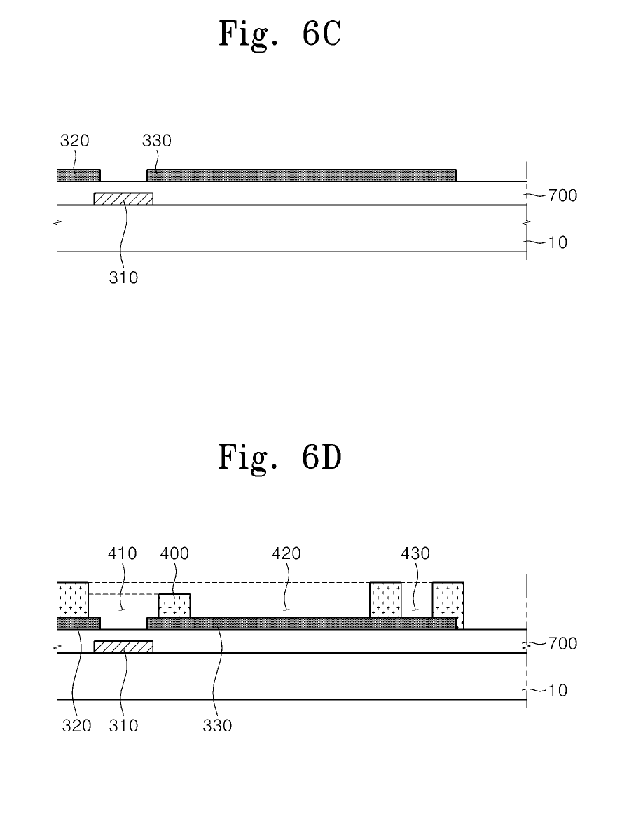

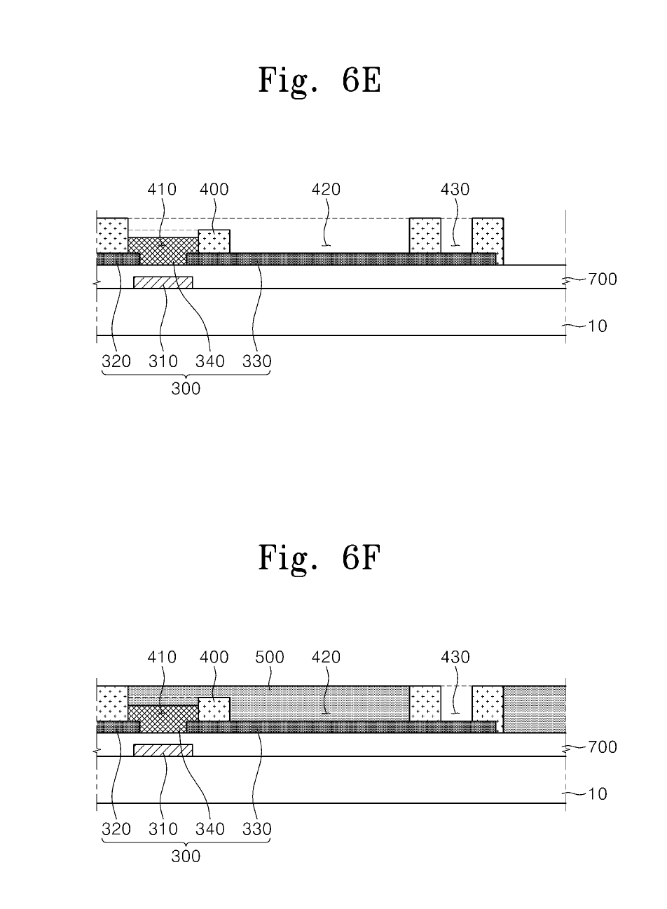

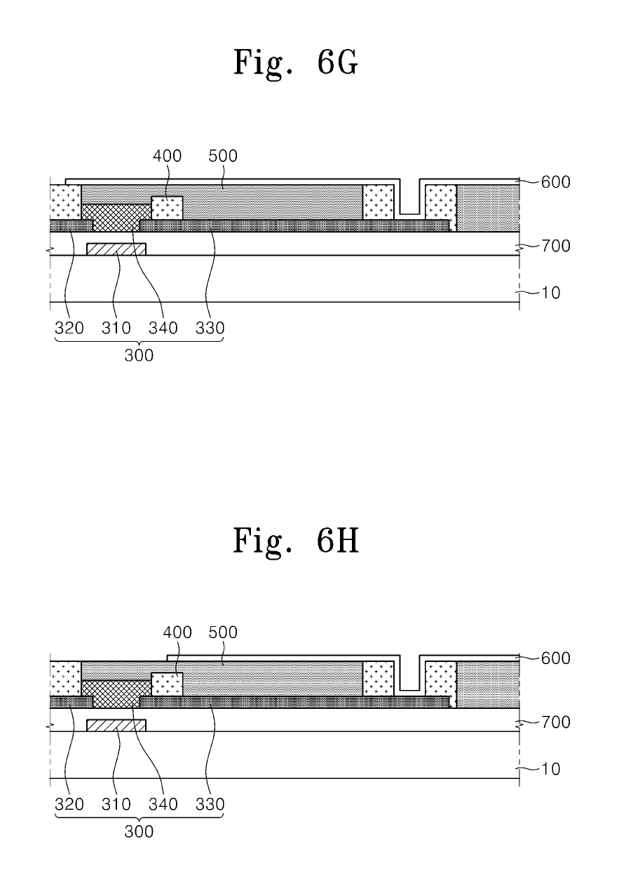

FIG. 6A, FIG. 6B, FIG. 6C, FIG. 6D. FIG. 6E, FIG. 6F, FIG. 6G, and FIG. 6H are diagrams showing a method of manufacturing the TFT substrate in accordance with the first and second exemplary embodiments of the present invention. The method of manufacturing the TFT substrate in accordance with this exemplary embodiment will be described with reference to FIG. 6A, FIG. 6B, FIG. 6C, FIG. 6D. FIG. 6E, FIG. 6F, FIG. 6G, and FIG. 6H.

First, a first metal pattern including a gate line (not shown) and a gate electrode 310 is formed as shown in FIG. 6A.

In particular, a metal layer, which may include a metal material, such as Cu, Mo, Al, Cu alloy, Mo alloy, and Al alloy, is deposited on an insulating substrate 10 by a deposition method such as sputtering, and the metal layer is patterned by a photolithography process and an etching process, thus forming the first metal pattern, which includes the gate line (not shown) and the gate electrode 310.

Next, a gate insulating layer 700 is formed on the first metal pattern, as shown in FIG. 6B.

The gate insulating layer 700 may be an inorganic insulating layer that includes silicon nitride (SiNₓ) or silicon oxide (SiOₓ) and is formed by a deposition method, such as plasma enhanced chemical vapor deposition (PECVD), an organic insulating layer formed by a coating or printing process, or a dual insulating layer formed by stacking an organic insulating layer and an inorganic insulating layer.

Then, a second metal pattern including a data line (not shown), a source electrode 320, and a drain electrode 330 is formed on the gate insulating layer 700, as shown in FIG. 6C.

A metal layer, which may include a metal material, such as Cu, Mo, Al, Cu alloy, Mo alloy, and Al alloy, is deposited on the gate insulating layer 700 by a deposition method such as sputtering, and the metal layer is patterned by a photolithography process and an etching process, thus forming the second metal pattern, which includes the data line (not shown), the source electrode 320, and the drain electrode 330 that is spaced apart from the source electrode 320.

Thereafter, a bank insulating layer 400 is formed on the second metal pattern and the gate insulating layer 700, as shown in FIG. 6D.

A photosensitive organic insulating material is coated by spinless or spin coating on the second metal pattern and the gate insulating layer 700, and the coated material is subjected to exposure and development processes using a mask, thus forming the bank insulating layer 400. The bank insulating layer 400 includes at least two partitions having different heights and provides regions where an organic semiconductor layer 340 and an organic passivation layer 500 are disposed. That is, the bank insulating layer 400 is provided in the form of partitions to provide a first hole 410 in which the organic semiconductor layer 340 is arranged and a second hole 420 in which the organic passivation layer 500 is arranged. The second hole 420 includes the first hole 410 so that the organic passivation layer 500 may cover the organic semiconductor layer 340. Moreover, the bank insulating layer 400 includes a third hole 430 to expose a portion of the drain electrode 330 so that the pixel electrode 600 may be connected to the drain electrode 330 through the third hole 430.

In order that the bank insulating layer 400 has different heights, a slit mask or a halftone mask as a photo mask is used at the exposure process. The slit mask or the halftone mask has a transmissive area, a non-transmissive area and an intermediate area. In the intermediate area, an interval between the slits is adjusted or a halftone material is used such that the light can partially pass through the intermediate area. As a result, the bank insulating layer 400 having a mean thickness is formed at an area corresponding to the intermediate area.

Subsequently, the organic semiconductor layer 340 is formed as shown in FIG. 6E.

The organic semiconductor layer 340 forms a channel between the drain electrode 330 and the source electrode 320 and overlaps the gate electrode 310. The organic semiconductor layer 340 may be formed by filling an organic semiconductor material in a liquid phase in the first hole 410 through an inkjet method and curing the same. In this case, the organic semiconductor material may be at least one of pentacene, tetracene, anthracene, naphthalene, α-6-thiophene, α-4-thiophene, perylene and derivatives thereof, rubrene and derivatives thereof, coronene and derivatives thereof, perylenetetracarboxylic diimide and derivatives thereof, perylenetetracarboxylic dianhydride and derivatives thereof, phthalocyanine and derivatives thereof, naphthalene tetracarboxylic diimide and derivatives thereof, naphthalene tetracarboxylic dianhydride and derivatives thereof, conjugated polymer derivatives containing substituted or non-substituted thiophene, and conjugated polymer derivatives containing substituted fluorine.

Next, the organic passivation layer 500 is formed, as shown in FIG. 6F.

The organic passivation layer 500 is provided to cover the organic semiconductor layer 340, thus protecting the organic semiconductor layer 340. The organic passivation layer 500 may be formed by filling a composition for forming an organic passivation layer in the second hole 420 and curing the same. The composition for the organic passivation layer contains a pigment or dye with other components such as a binder, a monomer, an initiator, an additive, and a solvent. In the composition for the organic passivation layer, the pigment or dye is added for color, the binder is added to aid dispersion stabilization and improve development effectiveness, and the monomer is added for photopolymerization and crosslinking. Moreover, the initiator is added to initiate the photopolymerization, the additive is added to improve the dispersion stabilization, coating properties and adhesion properties, and the solvent is added to improve the coating properties and processability. The composition for the organic passivation layer may include about 5 to about 10 wt % of the pigment or dye, about 5 to about 10 wt % of the binder, about 5 to about 10 wt % of the monomer, less than about 1 wt % of the initiator, less than about 1 wt % of the additive, and about 70 to about 85 wt % of the solvent.

Finally, the pixel electrode 600 is formed, as shown in FIG. 6G and FIG. 6H.

The pixel electrode 600 is connected to the drain electrode 330 through the third hole 430 provided by the bank insulating layer 400. The pixel electrode 600 may be formed on the whole surface of the sub-pixel region, as shown in FIG. 6G, or formed so as not to overlap the region where the TFT is formed, as shown in FIG. 6H. The pixel electrode 600 may include a transparent conductive material, such as ITO, IZO, etc., by a deposition method, such as sputtering.

As described above, according to the TFT substrate, the LCD having the same, and the method of manufacturing the same, since the organic passivation layer performs the function of a color filter, a color filter may be omitted, and thus it may be possible to simplify the manufacturing process and reduce manufacturing costs.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A thin film transistor substrate, comprising:
a gate line arranged on a substrate;
a data line arranged to cross the gate line;
an organic thin film transistor comprising a gate electrode connected to the gate line, a source electrode connected to the data line, a drain electrode spaced apart from the source electrode, and an organic semiconductor layer forming a channel between the source electrode and the drain electrode;
a pixel electrode connected to the drain electrode; and
an organic passivation layer to protect the organic semiconductor layer and to receive a light and transmit a colored light.

2. The thin film transistor substrate of claim 1, wherein the organic passivation layer overlaps with the pixel electrode.

3. The thin film transistor substrate of claim 1, further comprising a bank insulating layer having two portions with different heights from each other, the organic semiconductor layer and the organic passivation layer being arranged between the two portions.

4. The thin film transistor substrate of claim 3, wherein the two portions of the bank insulating layer are spaced apart from each other.

5. The thin film transistor substrate of claim 3, wherein the bank insulating layer comprises a first hole, in which the organic semiconductor layer is filled, and a second hole, in which the organic passivation layer is filled.

6. The thin film transistor substrate of claim 1, wherein the organic passivation layer transmits red, green, or blue light.

7. The thin film transistor substrate of claim 1, wherein the organic passivation layer comprises a pigment or dye.

8. The thin film transistor substrate of claim 7, wherein the organic passivation layer further comprises a binder, a monomer, an initiator, an additive, and a solvent.

9. The thin film transistor substrate of claim 8, wherein the organic passivation layer includes a composition comprising 5 to 10 wt % of the pigment or dye, 5 to 10 wt % of the binder, 5 to 10 wt % of the monomer, less than 1 wt % of the initiator, less than 1 wt % of the additive, and 70 to 85 wt % of the solvent.

10. The thin film transistor substrate of claim 5, wherein the first hole is included within the second hole.

11. A liquid crystal display, comprising:
a thin film transistor substrate;
an opposite substrate; and
a liquid crystal layer interposed between the thin film transistor substrate and the opposite substrate,
wherein the thin film transistor substrate comprises an organic thin film transistor comprising a gate electrode connected to a gate line, a source electrode connected to a data line, a drain electrode spaced apart from the source electrode, and an organic semiconductor layer forming a channel between the source electrode and the drain electrode, a pixel electrode connected to the drain electrode, and an organic passivation layer to protect the organic semiconductor layer and to receive a light and transmit a colored light.

12. The liquid crystal display of claim 11, wherein the organic passivation layer overlaps with the pixel electrode.

13. The liquid crystal display of claim 11, wherein the opposite substrate comprises a common electrode.

14. The liquid crystal display of claim 11, further comprising a bank insulating layer having two portions having different heights from each other, the organic semiconductor layer and the organic passivation layer being arranged between the two portions.

15. The liquid crystal display of claim 1 1, further comprising a backlight unit to provide the light, wherein the organic passivation layer receives the light from the backlight unit and transmits red, green, or blue light.

16. The liquid crystal display of claim 11, wherein the organic passivation layer comprises a pigment or dye.

17. The liquid crystal display of claim 16, wherein the organic passivation layer further comprises a binder, a monomer, an initiator, an additive, and a solvent.

18. The liquid crystal display of claim 14, wherein the bank insulating layer comprises a first hole, in which the organic semiconductor layer is filled, and a second hole, in which the organic passivation layer is filled, and
wherein the first hole is included within the second hole.

19. A method of manufacturing a thin film transistor substrate, the method comprising:
forming a first metal pattern including a gate line and a gate electrode on a substrate;
forming a second metal pattern comprising a data line, a source electrode, and a drain electrode spaced apart from the source electrode;
forming a bank insulating layer on the second metal pattern, the bank insulating layer comprising a first hole and a second hole;
forming an organic semiconductor layer in the first hole; and
forming an organic passivation layer in the second hole, the organic passivation layer to receive a light and transmit a colored light.

20. The method of claim 19, wherein the organic passivation layer comprises a pigment or dye.
